(19) United States
(12) Patent Application Publication
(10) Pub. No.: US 2025/0199134 A1
(43) Pub. Date: Jun. 19, 2025

(54) CONTROL DEVICE AND OPERATION METHOD THEREOF

(71) Applicant: Silicon Optronics, Inc., Hsinchu (TW)

(72) Inventors: Qingfeng LI, Hsinchu (TW); Xinping HE, Hsinchu (TW); Xiaodong LUO, Hsinchu (TW)

(21) Appl. No.: 18/669,791

(22) Filed: May 21, 2024

(30) Foreign Application Priority Data
Dec. 13, 2023 (CN) 202311715759.3

(51) Int. Cl. G01S 7/484; G01S 7/481; G01S 7/4865

(52) U.S. Cl. CPC G01S 7/484; G01S 7/4816; G01S 7/4865

(57) ABSTRACT

A control device suitable for use in a time-of-flight sensor is provided. The control device includes a storage unit and a control unit. The storage unit records the count data corresponding to the photon trigger number of the time-of-flight sensor. The control unit is coupled to the storage unit. The control unit reads the count data, obtains the modulation ratio corresponding to the counting range according to the count data, generates a control signal corresponding to the modulation ratio of each counting range, and transmits the control signal to the time-of-flight sensor, so as to control the operation of the time-of-flight sensor.

### CROSS REFERENCE TO RELATED APPLICATIONS

This application claims priority of China Patent Application No. 202311715759.3, filed on Dec. 13, 2023, the entirety of which is incorporated by reference herein.

### BACKGROUND OF THE INVENTION

### Field of the Invention

The present invention relates to a control device, and in particular it relates to a control device and an operation method thereof suitable for use in a time-of-flight sensor.

### Description of the Related Art

In general, a time-of-flight sensor (such as a single-photon avalanche diode (SPAD) sensor) may be used to sense the distance of a target object. When the light irradiates into the time-of-flight sensor to cause the time-of-flight sensor to be triggered, the time-of-flight sensor may generate an avalanche effect to cause the output signal of the time-of-flight sensor to toggle, and the time-of-flight sensor may count the toggling number of the corresponding signal to generate a corresponding count data. However, because ambient light is uncontrollable, the time-of-flight sensor may encounter high-frequency avalanche breakdown. This can increase the power consumption of the time-of-flight sensor, as well as increasing the storage requirements, thereby making the device less convenient to use.

Therefore, how to effectively decrease the power consumption of the time-of-flight sensor, as well as to decrease the storage requirements, has become a focus of technical improvements.

### BRIEF SUMMARY OF THE INVENTION

An embodiment of the present invention provides a control device and an operation method thereof, thereby effectively decreasing the power consumption of the time-of-flight sensor and the storage requirement, and increasing the convenience of use.

An embodiment of the present invention provides a control device suitable for use in a time-of-flight sensor. The control device includes a storage unit and a control device. The storage unit is configured to record the count data corresponding to the photon trigger number of the time-of-flight sensor. The control device is coupled to the storage unit. The control unit is configured to read the count data, obtain the modulation ratio corresponding to the counting range according to the count data, generate a control signal corresponding to the modulation ratio according to the modulation ratio, and transmit the control signal to the time-of-flight sensor, so as to control the operation of the time-of-flight sensor.

An embodiment of the present invention provides an operation method of a control device suitable for use in a time-of-flight sensor. The operation method of the control device includes the following steps. A storage unit is used to record the count data corresponding to the photon trigger number of the time-of-flight sensor. A control unit is used to read the count data. The control unit is used to obtain modulation ratio corresponding to the counting range according to the count data, and generate a control signal corresponding to the modulation ratio according to the modulation ratio. The control signal is transmitted to the time-of-flight sensor, so as to control the operation of the time-of-flight sensor.

According to the control device and the operation method thereof disclosed by the present invention, the control unit reads the count data corresponding to the photon trigger number of the time-of-flight sensor from the storage unit, obtains the modulation ratio corresponding to the counting range according to the counting value, generates the control signal corresponding to the modulation ratio, and transmits the control signal to the time-of-flight sensor, so as to control the operation of the time-of-flight sensor. Therefore, it may effectively decrease the power consumption of the time-of-flight sensor and the storage requirement, and increase the convenience of use.

### BRIEF DESCRIPTION OF THE DRAWINGS

The present invention can be more fully understood by reading the subsequent detailed description and examples with references made to the accompanying drawings, wherein:

FIG. 1 is a schematic view of a control device according an embodiment of the present invention;

FIG. 2 is a schematic view of a control unit according an embodiment of the present invention;

FIG. 3 is a flowchart of an operation method of a control device according an embodiment of the present invention;

FIG. 4 is a detailed flowchart of step S306 in FIG. 3; and

FIG. 5 is a flowchart of an operation method of a control device according another embodiment of the present invention.

### DETAILED DESCRIPTION OF THE INVENTION

In each of the following embodiments, the same reference number represents an element or component that is the same or similar.

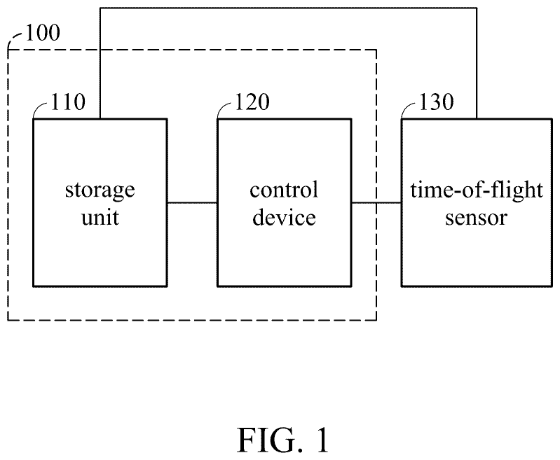

FIG. 1 is a schematic view of a control device according an embodiment of the present invention. The control device 100 of the embodiment is suitable for use in a time-of-flight sensor 130. In the embodiment, the time-of-flight sensor 130 is, for example, a single-photon avalanche diode (SPAD) sensor. When the time-of-flight sensor 130 (such as the SPAD sensor) operates and the light irradiates into the time-of-flight sensor 130 (such as the SPAD sensor) to cause the time-of-flight sensor 130 (such as the SPAD sensor) to be triggered, the time-of-flight sensor 130 (such as the SPAD sensor) may generate an avalanche effect and convert photons to generate small amount of electrons, and the above avalanche effect may cause the output signal of the time-of-flight sensor 130 (such as SPAD sensor) to toggle. The time-of-flight sensor 130 may count the toggling number of the signal, so as to generate the count data corresponding to the photon trigger number.

Please refer to FIG. 1. The control device 100 may include a storage unit 110 and a control device 120. The storage unit 110 may record the count data corresponding to the photon trigger number of the time-of-flight sensor 130. In some embodiments, the storage unit 110 is, for example, a static random access memory (SRAM), but the embodiment of the present invention is not limited thereto.

The control device 120 may be coupled to the storage unit 110. The control device 120 is, for example, a micro control unit (MCU), a microprocessor, or another suitable controller, but the embodiment of the present invention is not limited thereto.

The control unit 120 may read the count data from the storage unit 110. Then, the control unit 120 may obtain a modulation ratio corresponding to the counting range according to the count data. Furthermore, after the control unit 120 reads the count data, the control unit 120 may search in a lookup table according to the count data to obtain the count data, and obtain the modulation ratio corresponding to the counting range according to the counting range. In the embodiment, the duty cycle of the modulation ratio decreases as the counting range increases, for example. That is, when the counting range increases, the duty cycle of the modulation ratio decreases. When the counting range decreases, the duty cycle of the modulation ration increase. In addition, the duty cycle of the modulation ratio is (the turning-on time of the time-of-flight sensor 130/the frame time).

For example, when the counting range is, for example, the first range (such as 0-2047), the duty cycle of the modulation ratio is, for example, “1/1”. When the counting range is, for example, the second range (such as 2047-34815), the duty cycle of the modulation ratio is, for example, “1/32”. The rest of the corresponding relationships between the counting range and the duty cycle of the modulation may be deduced by analogy.

Afterward, the control unit 120 may generate the control signal corresponding to the modulation ratio (such as “1/1” or “1/32”) according to the above modulation ratio (such as “1/1” or “1/32”). In addition, the above control signal may be a pulse width modulation (PWM) signal. Then, the control unit 120 may transmit the control signal to the time-of-flight sensor 130, so as to control the operation of the time-of-flight sensor 130. Therefore, it may effectively decrease the power consumption of the time-of-flight sensor 130 and the storage requirement of the storage unit 110. For example, assuming that the counting range of the time-of-flight sensor 130 is, for example, 1,000,000, 20 bits of storage and calculation may be required. However, through the operation of the control unit 120 of the embodiment of the present invention, only 12 bits of storage and calculation are required, and the power consumption of the time-of-flight sensor may be decreased to 1/250 of the original.

In some embodiment, after the control unit 120 reads the count data, the control unit 120 may determine whether the count data is within a first range (for example, the control unit 120 determines whether the counting range is the first range). When the control unit 120 determines that the count data is within the first range (for example, the control unit determines that the counting range is the first range), the control unit 120 may obtain a first modulation ratio corresponding to the first range, and generate the control signal corresponding to the first modulation ratio according to the first modulation ratio. In the embodiment, the first range is, for example, 0-2047, wherein “0” is the lower limit of the first range, and “2047” is the upper limit of the first range, but the embodiment of the present invention is not limited thereto. In addition, the first modulation ratio is, for example, 1/1”, wherein the numerator “1” is the turning-on time of the time-of-flight sensor 130 and the denominator “1” is the frame time, but the embodiment of the present invention is not limited thereto.

When the control unit 120 determines that the count data is not within the first range (for example, the control determines that the counting range is not the first range), the control unit 120 may determine whether the count data is within a second range (for example, the control unit 120 determines whether the counting range is the second range). When the control unit 120 determines that the count data is within the second range (for example, the control unit 120 determines that the counting range is the second range), the control unit 120 may obtain a second modulation ratio corresponding to the second range, and generate the control signal corresponding to the second modulation ratio according to the second modulation ratio. In the embodiment, the second range may be different from the first range. Furthermore, the second range may be greater than the first range, and the second range is, for example, 2047-34815, wherein “2047” is the lower limit of the second range and “34815” is the upper limit of the second range, but the embodiment of the present invention is not limited thereto. In addition, the second modulation ratio is different from the first modulation ratio. Furthermore, the second modulation ratio is, for example, “1/32”, wherein the numerator “1” is the turning-on time of the time-of-flight sensor 130 and the denominator “32” is the frame time, but the embodiment of the present invention is not limited thereto.

When the control unit 120 determines that the count data is not within the second range (for example, the control unit 120 determines that the counting range is not the second range), the control unit 120 may determine whether the count data is within a third range (for example, the control unit 120 determines whether the counting range is the third range). When the control unit 120 determines that the count data is within the third range (for example, the control unit 120 determines that the counting range is the third range), the control unit 120 may obtain a third modulation ratio corresponding to the third range, and generate the control signal corresponding to the third modulation ratio according to the third modulation ratio. In the embodiment, the third range may be different from the second range. Furthermore, the third range may be greater than the second range, and the third range is, for example, 34815-452607, wherein “34815” is the lower limit of the third range and “452607” is the upper limit of the third range, but the embodiment of the present invention is not limited thereto. In addition, the third modulation ratio is different from the second modulation ratio. Furthermore, the third modulation ratio is, for example, 1/544”, wherein the numerator “1” is the turning-on time of the time-of-flight sensor 130 and the denominator “544” is the frame time, but the embodiment of the present invention is not limited thereto.

When the control unit 120 determines that the count data is not within the third range (for example, the control unit 120 determines that the counting range is not the third range), the control unit 120 may determine whether the count data is within a fourth range (for example, the control unit 120 determines whether the counting range is the fourth range). When the control unit 120 determines that the count data is within the fourth range (for example, the control unit 120 determines that the counting range is the fourth range), the control unit 120 may obtain a fourth modulation ratio corresponding to the third range, and generate the control signal corresponding to the third modulation ratio according to the third modulation ratio. In the embodiment, the fourth range may be different from the third range. Furthermore, the fourth range may be greater than the third range, and the fourth range is, for example, 452607-1048575, wherein “452607” is the lower limit of the fourth range and “1048575” is the upper limit of the fourth range, but the embodiment of the present invention is not limited thereto. In addition, the fourth modulation ratio is different from the third modulation ratio. Furthermore, the fourth modulation ratio is, for example, “1/7072”, wherein the numerator “1” is the turning-on time of the time-of-flight sensor 130 and the denominator “7072” is the frame time, but the embodiment of the present invention is not limited thereto.

In some embodiments, the control unit 120 further reads current data corresponding to the time-of-flight sensor 130 from the storage unit 110. The control unit 120 may generate recovery data according to the current data, the lower limit of the counting range, the data compression ratio, and the frame time of the modulation ratio of the control signal.

In the embodiment, the recovery data may be expressed by equation (1):

$$cnt ’ = ( cnt - CR ) * R + L 1 , \qquad ( 1 )$$

wherein ent′ is the recovery data, cnt is the current data, LI is the lower limit of the counting range, CR is the data compression ratio and R is the frame time of the modulation ratio of the control signal.

In some embodiments, when the count data corresponding to the current data is the first range, since the first modulation ratio is “1/1”, the data compression ratio is “0” and the lower limit of the first range is “0”, the recovery data is the same current data, and the recovery data may be expressed by equation (2):

$$cnt 1 ’ = ( cnt 1 - 0 ) * 1 + 0 = cnt 1 , \qquad ( 2 )$$

wherein cnt1′ is the recovery data and cnt1 is the current data.

In some embodiments, when the count data corresponding to the current data is the second range, the recovery data may be expressed by equation (3):

$$cnt 2 ’ = ( cnt 2 - CR 2 ) * R 2 + LI 2 , \qquad ( 3 )$$

wherein cnt2′ is the recovery data, cnt2 is the current data, LI2 is the lower limit of the second range (such as 2047), CR2 is the data compression ratio corresponding to the second range (such as 2047) and R2 is the frame time of the second modulation ratio of the control signal (such as 32).

In some embodiments, when the count data corresponding to the current data is the third range, the recovery data may be expressed by equation (4):

$$cnt 3 ’ = ( cnt 3 - CR 3 ) * R 3 + LI 3 , \qquad ( 4 )$$

wherein cnt3′ is the recovery data, cnt3 is the current data, LI3 is the lower limit of the third range (such as 34815), CR2 is the data compression ratio corresponding to the third range (such as 3071) and R2 is the frame time of the third modulation ratio of the control signal (such as 544).

In some embodiments, when the count data corresponding to the current data is the fourth range, the recovery data may be expressed by equation (5):

$$cnt 4 ’ = ( cnt 4 - CR 4 ) * R 4 + LI 4 , \qquad ( 5 )$$

wherein cnt4′ is the recovery data, cnt4 is the current data, LI4 is the lower limit of the fourth range (such as 452607), CR4 is the data compression ratio corresponding to the fourth range (such as 3839) and R4 is the frame time of the fourth modulation ratio of the control signal (such as 7072).

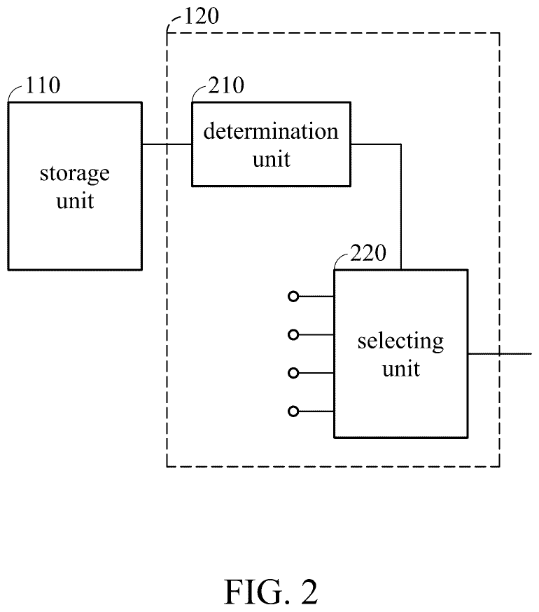

FIG. 2 is a schematic view of a control unit according an embodiment of the present invention. Please refer to FIG. 2. The control unit 120 includes a determination unit 210 and a selecting unit 220.

The determination unit 210 may be coupled to the storage unit 110. The determination unit 210 may read the count data, and determine whether the count data is within the first range (for example, the determination unit 210 determines whether the counting range is the first range). When the determination unit 210 determines that the count data is within the first range (for example, the determination unit 210 determines that the counting range is the first range), the determination unit 210 may generate a first selecting signal corresponding to the first range.

When the determination unit 210 determines that the count data is not within the first range (for example, the determination unit 210 determines that the counting range is not the first range), the determination unit 210 may determine whether the count data is within the second range (for example, the determination unit 210 determines whether the counting range is the second range). When the determination unit 210 determines that the count data is within the second range (for example, the determination unit 210 determines that the counting range is the second range), the determination unit 210 may generate a second selecting signal corresponding to the second range. When the determination unit 210 determines that the count data is not within the second range (for example, the determination unit 210 determines that the counting range is not the second range), the determination unit 210 may determine whether the count data is within the third range (for example, the determination unit 210 determines whether the counting range is the third range).

When the determination unit 210 determines that the count data is within the third range (for example, the determination unit 210 determines that the counting range is the third range), the determination unit 210 may generate a third selecting signal corresponding to the third range. When the determination unit 210 determines that the count data is not within the third range (for example, the determination unit 210 determines that the counting range is not the third range), the determination unit 210 may determine whether the count data is within the fourth range (for example, the determination unit 210 determines whether the counting range is the fourth range). When the determination unit 210 determines that the count data is within the fourth range (for example, the determination unit 210 determines that the counting range is the fourth range), the determination unit 210 may generate a fourth selecting signal corresponding to the fourth range.

The selecting unit 220 may be coupled to the determination unit 210. The selecting unit 220 may receive the control signal with a duty cycle of the first modulation ratio, the control signal with a duty cycle of the second modulation ratio, the control signal with a duty cycle of the third modulation ratio and the control signal with a duty cycle of the fourth modulation ratio. When the selecting unit 220 receives the first selecting signal, the selecting unit 220 may select and generate the control signal with the duty cycle of the first modulation ratio. When the selecting unit 220 receives the second selecting signal, the selecting unit 220 may select and generate the control signal with the duty cycle of the second modulation ratio. When the selecting unit 220 receives the third selecting signal, the selecting unit 220 may select and generate the control signal with the duty cycle of the third modulation ratio. When the selecting unit 220 receives the fourth selecting signal, the selecting unit 220 may select and generate the control signal with the duty cycle of the fourth modulation ratio. In the embodiment, the selecting unit 220 may be a multiplexer (MUX), but the embodiment of the present invention is not limited thereto.

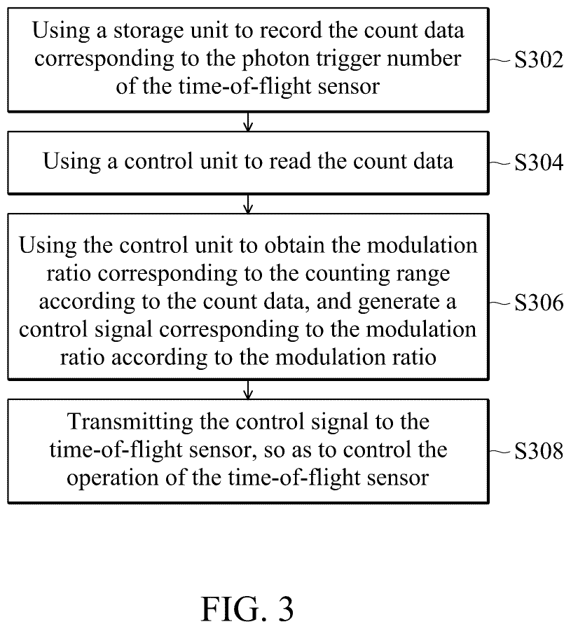

FIG. 3 is a flowchart of an operation method of a control device according an embodiment of the present invention. The operation method of the control device of the embodiment is suitable for use in a time-of-flight sensor. In step S302, the method involves using a storage unit to record the count data corresponding to the photon trigger number of the time-of-flight sensor. In step S304, the method involves using a control unit to read the count data.

In step S306, the method involves using the control unit to obtain the modulation ratio corresponding to the counting range according to the count data, and generate a control signal corresponding to the modulation ratio according to the modulation ratio. In step S308, the method involves transmitting the control signal to the time-of-flight sensor, so as to control the operation of the time-of-flight sensor. In some embodiments, the duty cycle of the above modulation ratio decreases as the counting range increases.

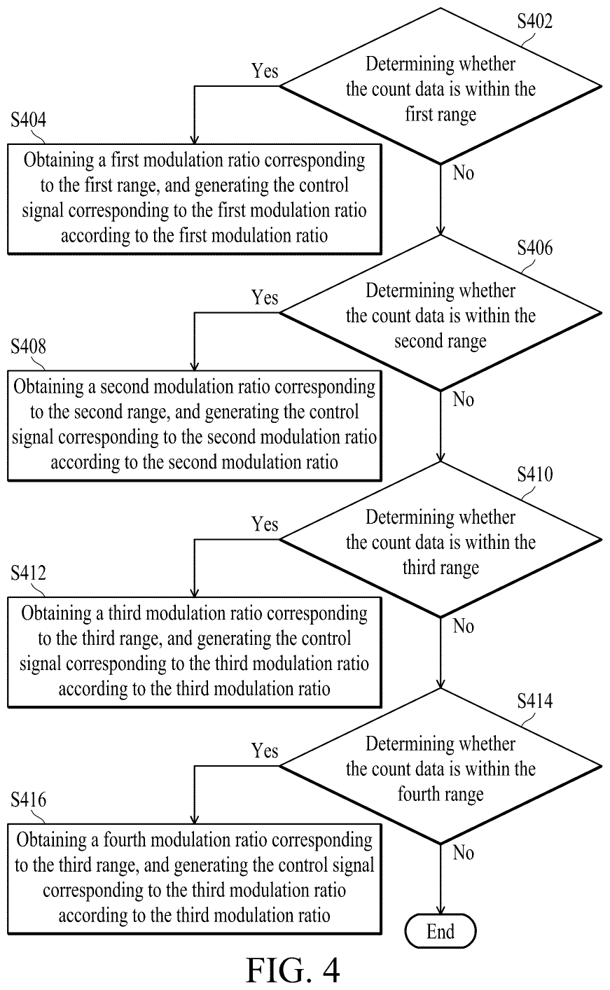

FIG. 4 is a detailed flowchart of step S306 in FIG. 3. In step S402, the method involves determining whether the count data is within the first range. When determining that the count data is within the first range, the method performs step S404. In step S404, the method involves obtaining a first modulation ratio corresponding to the first range, and generating the control signal corresponding to the first modulation ratio according to the first modulation ratio. When determining that the count data is not within the first range, the method performs step S406. In step S406, the method involves determining whether the count data is within the second range.

When determining that the count data is within the second range, the method performs step S408. In step S408, the method involves obtaining a second modulation ratio corresponding to the second range, and generating the control signal corresponding to the second modulation ratio according to the second modulation ratio. When determining that the count data is not within the second range, the method performs step S410. In step S410, the method involves determining whether the count data is within the third range. When determining that the count data is within the third range, the method performs step S412. In step S412, the method involves obtaining a third modulation ratio corresponding to the third range, and generating the control signal corresponding to the third modulation ratio according to the third modulation ratio.

When determining that the count data is not within the third range, the method performs step S414. In step S414, the method involves determining whether the count data is within the fourth range. When determining that the count data is within the fourth range, the method performs step S416. In step S416, the method involves obtaining a fourth modulation ratio corresponding to the third range, and generating the control signal corresponding to the third modulation ratio according to the third modulation ratio. When determining that the counting range is not the fourth range, the operation process ends. In the embodiment, the first range, the second range, the third range and the fourth range are different, and the first modulation ratio, the second modulation ratio, the third modulation ratio and the fourth modulation ratio are different.

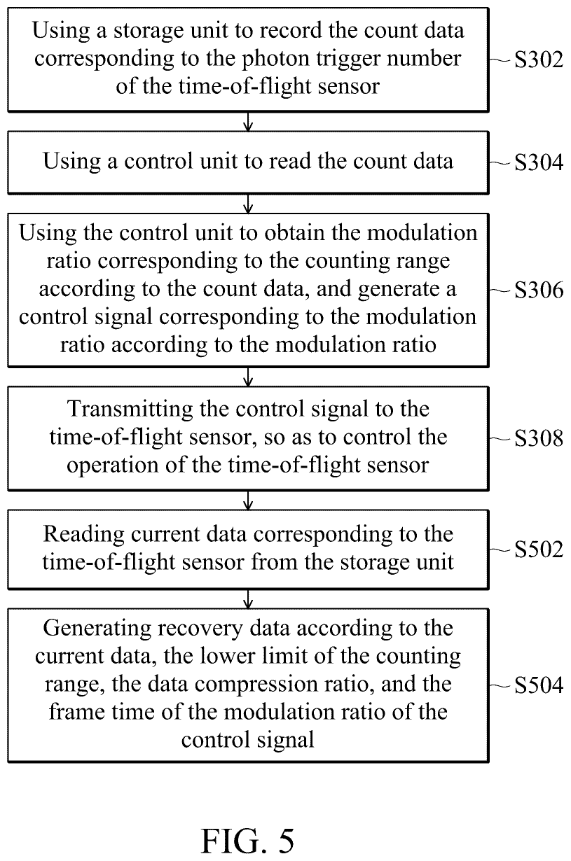

FIG. 5 is a flowchart of an operation method of a control device according another embodiment of the present invention. In the embodiment, steps S302-S308 in FIG. 5 are the same as or similar to steps S302-S308 in FIG. 3. Accordingly, steps S302-S308 in FIG. 5 may refer to description of the embodiment of FIG. 3, and the description thereof is not repeated herein. In step S502, the method involves reading current data corresponding to the time-of-flight sensor from the storage unit. In step S504, the method involves generating recovery data according to the current data, the lower limit of the counting range, the data compression ratio, and the frame time of the modulation ratio of the control signal.

In summary, according to the control device and the operation method thereof disclosed by the embodiment of the present invention, the control unit reads the count data corresponding to the photon trigger number of the time-of-flight sensor from the storage unit, obtains the modulation ratio corresponding to the counting range according to the count data, generates the control signal corresponding to the modulation ratio according to the modulation ratio, and transmits the control signal to the time-of-flight sensor, so as to control the operation of the time-of-flight sensor. In addition, the embodiment may further read the current data corresponding to the time-of-flight sensor from the storage unit, and generate the recovery data according to the current data, the lower limit of the counting range, the data compression ratio and the frame time of the modulation ratio of the control signal. Therefore, it may effectively decrease the power consumption of the time-of-flight sensor and the storage requirement, and increase the convenience of use.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A control device, suitable for use in a time-of-flight sensor, wherein the control device comprises:
a storage unit, configured to record a count data corresponding to a photon trigger number of the time-of-flight sensor; and
a control device, coupled to the storage unit, wherein the control unit is configured to read the count data, obtain a modulation ratio corresponding to a counting range according to the count data, generate a control signal corresponding to the modulation ratio according to the modulation ratio, and transmit the control signal to the time-of-flight sensor, so as to control an operation of the time-of-flight sensor.

2. The control device as claimed in claim 1, wherein a duty cycle of the modulation ratio decreases as the counting range increases.

3. The control device as claimed in claim 1, wherein the control unit is configured to determine whether the count data is within a first range;
when the control unit determines that the counting range is the first range, the control unit is configured to obtain a first modulation ratio corresponding to the first range, and generate the control signal corresponding to the first modulation ratio according to the first modulation ratio;
when the control unit determines that the counting range is not the first range, the control unit is configured to determine whether the count data is within a second range;
when the control unit determines that the counting range is the second range, the control unit is configured to obtain a second modulation ratio corresponding to the second range, and generate the control signal corresponding to the second modulation ratio according to the second modulation ratio;
when the control unit determines that the counting range is not the second range, the control unit is configured to determine whether the count data is within a third range;
when the control unit determines that the counting range is the third range, the control unit is configured to obtain a third modulation ratio corresponding to the third range, and generate the control signal corresponding to the third modulation ratio according to the third modulation ratio;
when the control unit determines that the counting range is not the third range, the control unit is configured to determine whether the count data is within a fourth range; and
when the control unit determines that the counting range is the fourth range, the control unit is configured to obtain a fourth modulation ratio corresponding to the third range, and generate the control signal corresponding to the third modulation ratio according to the third modulation ratio.

4. The control device as claimed in claim 3, wherein the first range, the second range, the third range and the fourth range are different, and the first modulation ratio, the second modulation ratio, the third modulation ratio and the fourth modulation ratio are different.

5. The control device as claimed in claim 3, wherein the control unit comprises:
a determination unit, configured to read the count data, and determine whether the count data is within the first range, wherein when the determination unit determines that the count data is within the first range, the determination unit is configured to generate a first selecting signal corresponding to the first range; when the determination unit determines that the count data is not within the first range, the determination unit is configured to determine whether the count data is within the second range; when the determination unit determines that the count data is within the second range, the determination unit is configured to generate a second selecting signal corresponding to the second range; when the determination unit determines that the count data is not within the second range, the determination unit is configured to determine whether the count data is within the third range; when the determination unit determines that the count data is within the third range, the determination unit is configured to generate a third selecting signal corresponding to the third range; when the determination unit determines that the count data is not within the third range, the determination unit is configured to determine whether the count data is within the fourth range; when the determination unit determines that the count data is within the fourth range, the determination unit is configured to generate a fourth selecting signal corresponding to the fourth range; and
a selecting unit, coupled to the determination unit, wherein the selecting unit is configured to receive the first selecting signal to generate the control signal with a duty cycle of the first modulation ratio, the selecting unit is configured to receive the second selecting signal to generate the control signal with a duty cycle of the second modulation ratio, the selecting unit is configured to receive the third selecting signal to generate the control signal with a duty cycle of the third modulation ratio, and the selecting unit is configured to receive the fourth selecting signal to generate the control signal with a duty cycle of the fourth modulation ratio.

6. The control device as claimed in claim 1, wherein the control unit is further configured to read current data corresponding to the time-of-flight sensor from the storage unit, and generate recovery data according to the current data, a lower limit of the counting range, a data compression ratio and a frame time of the modulation ratio of the control signal.

7. An operation method of a control device, suitable for use in a time-of-flight sensor, wherein the operation method of the control device comprises:
using a storage unit to record a count data corresponding to a photon trigger number of the time-of-flight sensor;
using a control unit to read the count data;
using the control unit to obtain a modulation ratio corresponding to a counting range according to the count data, and generate a control signal corresponding to the modulation ratio according to the modulation ratio; and
transmitting the control signal to the time-of-flight sensor, so as to control an operation of the time-of-flight sensor.

8. The operation method of the control device as claimed in claim 7, wherein a duty cycle of the modulation ratio decreases as the counting range increases.

9. The operation method of the control device as claimed in claim 7, wherein the step of obtaining the modulation ratio corresponding to the counting range according to the count data, and generating the control signal corresponding to the modulation ratio according to the modulation ratio comprises:
determining whether the count data is within a first range;
when determining that the count data is within the first range, obtaining a first modulation ratio corresponding to the first range, and generating the control signal corresponding to the first modulation ratio according to the first modulation ratio;
when determining that the count data is not within the first range, determining whether the count data is within a second range;
when determining that the count data is within the second range, obtaining a second modulation ratio corresponding to the second range, and generating the control signal corresponding to the second modulation ratio according to the second modulation ratio;
when determining that the count data is not within the second range, determining whether the count data is within a third range;
when determining that the count data is within the third range, obtaining a third modulation ratio corresponding to the third range, and generating the control signal corresponding to the third modulation ratio according to the third modulation ratio;
when determining that the count data is not within the third range, determining whether the count data is within a fourth range; and
when determining that the count data is within the fourth range, obtaining a fourth modulation ratio corresponding to the third range, and generating the control signal corresponding to the third modulation ratio according to the third modulation ratio.

10. The operation method of the control device as claimed in claim 9, wherein the first range, the second range, the third range and the fourth range are different, and the first modulation ratio, the second modulation ratio, the third modulation ratio and the fourth modulation ratio are different.

11. The operation method of the control device as claimed in claim 7, further comprising:
reading current data corresponding to the time-of-flight sensor from the storage unit; and
generating recovery data according to the current data, a lower limit of the counting range, a data compression ratio and a frame time of the modulation ratio of the control signal.
